(19) United States
(12) Patent Application Publication
(10) Pub. No.: US 2005/0074934 A1
(43) Pub. Date: Apr. 7, 2005

(54) Electrodeposited layer

(76) Inventor: Jean-Louis Guyot, Dole (FR)

Correspondence Address: Leon D. Rosen;FREILICH, HORNBAKER & ROSEN, Suite 1220, 10960 Wilshire Blvd., Los Angeles, CA, 90024, US

(21) Appl. No.: 10/783,239

(22) Filed: Feb. 19, 2004

Related U.S. Application Data
(63) Continuation-in-part of application No. PCT/FR02/02929, filed on Aug. 23, 2002.

(30) Foreign Application Priority Data
Aug. 24, 2001 (FR) 0111070

(51) Int. Cl. H01L 21/8238

(52) U.S. Cl. 438/200

(57) ABSTRACT

A thin layer of precious metal that is electroplated through a mask onto a conductive substrate, as to form gold plated contacts, is formed with numerous microscopic recesses to produce a microscopically rough surface and to reduce the amount of gold or other precious metal that is used for a layer of predetermined thickness. A screen formed with microscopic holes, such as a woven mesh, lies between an elastomeric mask that defines the outline of the deposited layer and a face of the metal substrate, the screen being compressed between them. The combination is dipped in an electrolytic bath, where electrolyte flows through the microscopic holes of the screen, so the metal is plated on a face of the substrate, but is plated with recesses where threads of the screen have laid adjacent to the substrate face.

### CROSS-REFERENCE TO RELATED APPLICATION

This is a continuation-in-part of PCT application PCT/FR02/02929 filed Aug. 23, 2002, which claimed priority from French Application No. 0111070 filed Aug. 24, 2001.

### BACKGROUND OF THE INVENTION

Sheet metal, especially in the form of continuous strips, are commonly plated with precious metal such as gold, silver or an alloy of them. For example, a strip from which contacts are to be punched out may be plated with gold to reduce corrosion. To reduce the cost of the gold, the plating is thin, such as on the order of magnitude of one micron. A minimum thickness is required to assure that areas of the substrate will not go unplated and to provide wear resistance. An electrodeposition method that further reduced the amount of precious metal that was plated and produced a microscopically roughened surface would be of value.

### SUMMARY OF THE INVENTION

In accordance with one embodiment of the present invention, a plating, plating method, and plating apparatus are provided for the electrodeposition of a metal on a substrate, which reduces the amount of precious metal that is used when a plating of predetermined maximum local thickness of precious metal is to be applied to the substrate and which produces a microscopically roughened surface. The method includes maintaining a screen with microscopic openings, such as with widths and lengths each on the order of magnitude of 0.1 millimeter, closely over the area of the substrate to be plated. The screen can be formed of woven threads to have regularly spaced openings through which electrolyte can flow so at least the middles of the openings are plated to a predetermined thickness. However, areas under the threads of the screen receive reduced amounts of the electrolyte and are plated to reduced thicknesses. The reductions in thickness at microscopically spaced areas of the plating, reduce the amount of precious metal that is used, and create a microscopic roughness pattern in the plating.

The substrate is usually in the form of a continuous strip that moves with the screen and the mask, around a large diameter wheel into a liquid electrolyte where precious metal plating occurs. The fact that the screen and other elements are wrapped around the wheel, facilitates maintaining the screen and other elements in intimate contact by maintaining them in tension. The screen can be bonded, as by adhesive, to the mask to hold it in place.

The novel features of the invention are set forth with particularity in the appended claims. The invention will be best understood from the following description when read in conjunction with the accompanying drawings.

### BRIEF DESCRIPTION OF THE DRAWINGS

FIG. 1 is a sectional view of a strip of plating apparatus of the present invention

FIG. 2 is an exploded isometric view of the elements of the apparatus of FIG. 1.

FIG. 3 is an enlarged sectional view of a portion of the substrate and screen of FIG. 1.

FIG. 4 is an enlarged sectional view of the substrate of FIG. 3, after a metal coating has been plated on it through the screen, and the screen has been removed.

FIG. 5 is an enlarged isometric view of the substrate with the coating of FIG. 4 thereon.

FIG. 6 is a sectional view of the apparatus of FIG. 2 used in a method for depositing a coating on the substrate.

FIG. 7 is a side view of the apparatus of FIG. 6.

FIG. 8 is an enlarged plan view of one form of screen used in the method of FIG. 6.

### DESCRIPTION OF THE PREFERRED EMBODIMENTS

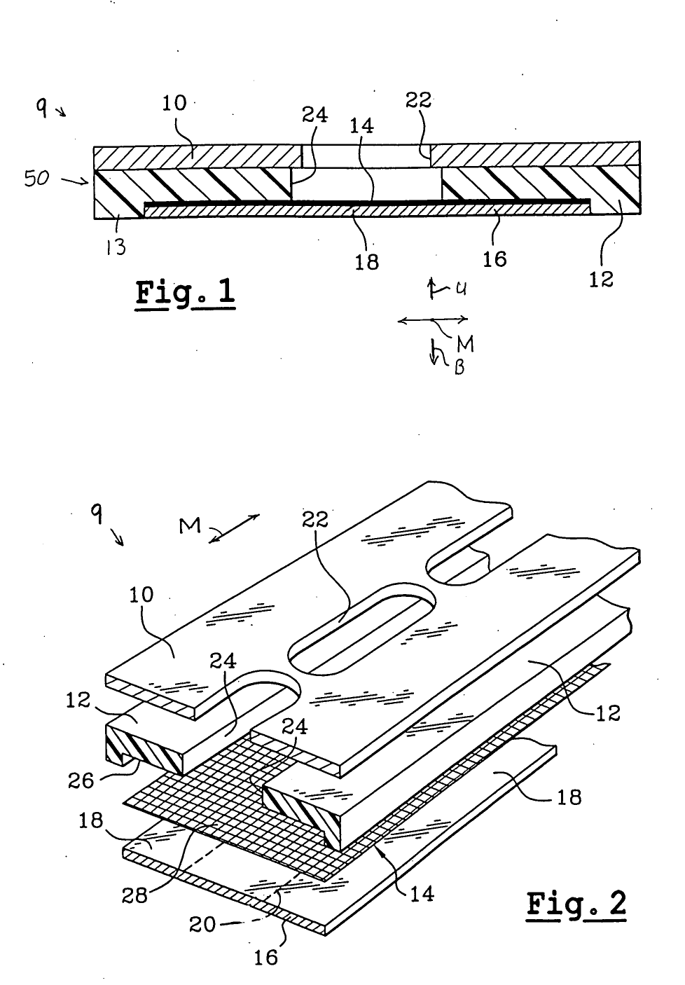

FIGS. 1 and 2 illustrate an apparatus 9 that includes a sheet metal substrate 16 in the form of a strip that is elongated in a longitudinal direction M, and that is to be plated with a precious metal such as gold. A precious metal is here defined as one whose cost is at least as great as silver (presently about $5 per ounce). The apparatus includes a stack of elements including an upper support 10, a mask 50 formed by two mask belts 12, 13, and a screen 14. The apparatus is used to deposit a thin layer, or coating of precious metal, the layer at 20 in FIG. 2 being shown in the form of a strip. In one example, lengths of the strip are used as switch contacts, with the plated gold layer providing corrosion resistance. The upper support 10 (direction U) is formed of electrically nonconductive material, and the mask belts 12, 13 are each formed of nonconductive elastomeric material and may be fastened to the support by adhesive. The substrate 18 is shown at the bottom B.

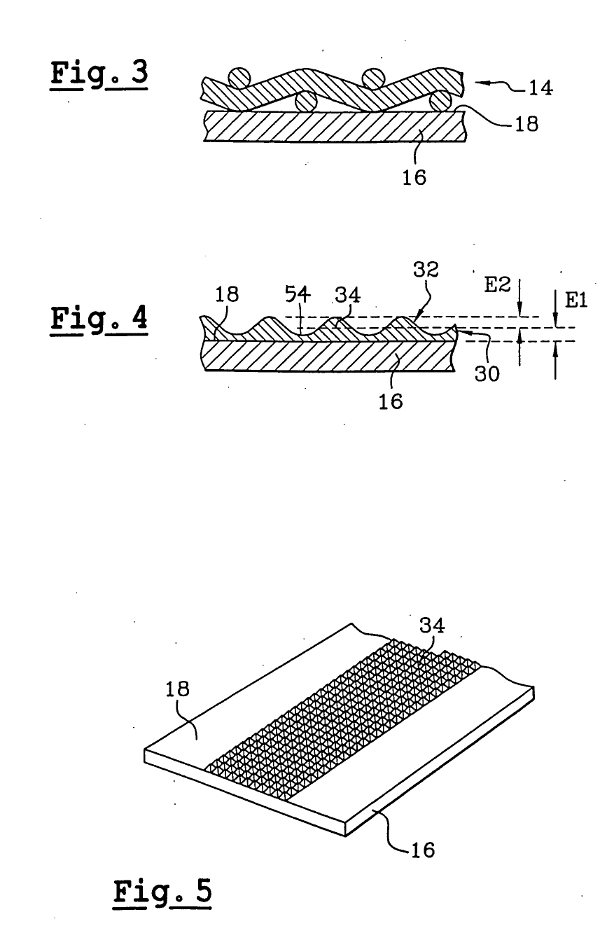

In accordance with the invention, the stencil or screen 14, shown in FIG. 2, is provided to reduce the amount of precious metal that is deposited and to create a microscopically roughened (distance between peaks and adjacent valleys is no more than 0.01 inch) exposed surface. The screen, shown in FIG. 8, has solid screen walls 52 and has holes 28 between adjacent walls. During electroplating, electrolyte can pass through the holes so precious metal can be deposited on the substrate 16 (FIG. 2) in full thickness at the middle of each hole, and can be deposited in reduced thickness between the holes. As shown in FIG. 4, this can result in an electrodeposited coating 30 whose surface 32 has a regular pattern of peaks 34 and valleys 54 corresponding to the pattern of the screen.

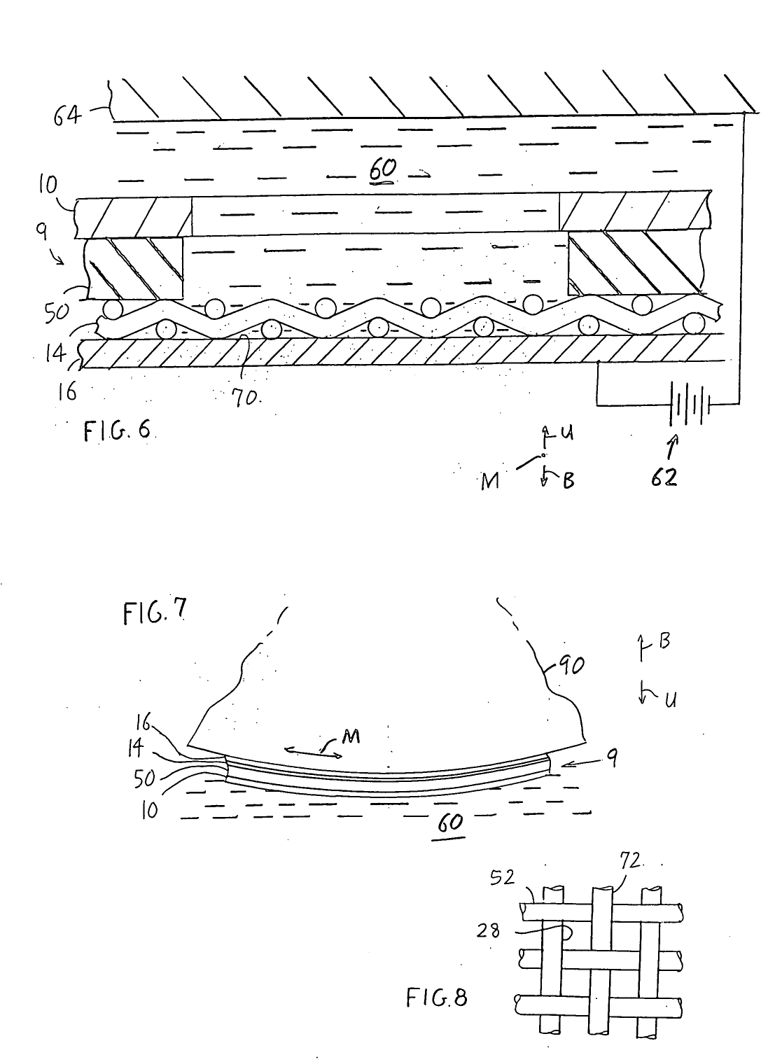

FIGS. 6 and 7 show a process for depositing the layer of precious metal. In FIG. 6, the apparatus 9 that includes the substrate 16, the screen 14, mask 50, and support 10, are dipped in a bath of electrolyte 60. A voltage source 62 is connected between the substrate 16 as a cathode and a quantity of gold 64 as an anode. Gold flows from the cathode 64 though the electrolyte 60 to the metal substrate 16 to plate its upper face 70. In FIGS. 6 and 8, the screen is shown as a woven screen, with threads 72 of round cross section forming the holes 28 between threads. Electrolyte flows though the holes, but the thickness of electrolyte under the threads is microscopically small (less than 0.1 millimeter thick) and plates less gold under the threads, resulting in the plated layer having a reduced thickness under the threads. The result is a regular pattern of peaks 34 (FIG. 4) and valleys 54, corresponding to the pattern of the screen.

The walls 52 (FIG. 8) between the holes 28 are at a microscopic pitch such as 0.1 millimeter. In one example, where the gold plating has a maximum thickness E1+E2 (FIG. 4) on the order of magnitude of one micron (actually 0.2 to 2 microns), and the screen pitch is 0.085 mm with each screen opening or hole having an area of 25×10⁻⁴ mm², the mean thickness E1 of the coating is 60% to 70% of the maximum thickness. This results in saving of precious metal. Applicant notes that a certain thickness of gold plating is specified to be sure that a continuous plating layer is deposited. Applicant's recesses in the layer leave a continuous coating.

FIG. 7 shows one way in which the metal substrate as an elongated, or continuous strip, is plated. The apparatus 9 that comprises the support 10, mask 50, screen 14 and substrate 16 are all in the form of strips, and are wrapped around a wheel 90. The wheel is slowly rotated to move the apparatus into a bath of the electrolyte 60, while a voltage is applied to a quantity of gold and to the substrate to plate the substrate.

The screen can be formed in a variety of ways including etching or otherwise forming holes in a thin plate of electrically nonconductive material. However, applicant prefers to use a screen woven from threads having round perimeters, to produce sloping recesses in the final coating. The screen can be made to lie very close to the substrate at locations within openings in the mask by tension or other means.

Thus, the invention provides a method for producing an electrodeposited layer or coating of metal having a thickness on the order of magnitude of one micron on a metal substrate, apparatus for producing such coating, and the combination of a metal substrate and such coating, wherein the coating has a microscopic roughness (distance between peaks and adjacent valleys is no more than about 0.01 inch and preferably no more than 0.1 millimeter) on its exposed surface. Where the coating is of precious metal this can reduce the amount of precious metal to lower costs. The rough surface also can be useful in applications were a microscopically rough surface is desired. The method includes placing a screen having microscopically spaced holes and microscopically thick walls between holes walls, against a surface of a metal substrate. A mask that is preferably elastomeric presses the screen against portions of the substrate that are not to be plated. The screen-covered substrate is placed in an electrolyte, so electrolyte flows through holes in the screen and carries the plating metal such as gold to the substrate to plate it, but with the electrolyte and plating being thinned under the threads or other walls of the screen.

Although particular embodiments of the invention have been described and illustrated herein, it is recognized that modifications and variations may readily occur to those skilled in the art, and consequently, it is intended that the claims be interpreted to cover such modifications and equivalents.

1. A method for depositing an electrically conductive layer of precious metal on a face of a metal substrate by maintaining a mask closely over the substrate face while the face and mask are immersed in an electrolyte and the precious metal is electrodeposited through the electrolyte onto the substrate face, comprising:
maintaining a screen closely between said mask and said substrate face, said screen having a regular pattern of through holes, and including flowing the electrolyte into said through hole and against the substrate face, and electrodepositing the precious metal through the electrolyte lying in said holes onto the substrate face.

2. The method described in claim 1 wherein:
said screen is formed of multiple wires that each have a rounded periphery.

3. The method described in claim 1 wherein:
said step of electroplating includes depositing said precious metal to an average thickness of less than 5 microns.

4. The method described in claim 1 wherein:
said screen is woven of threads of round cross-section, that form multiple primarily square openings that each have a width and length on the order of 85 microns.

5. The method described in claim 1 wherein:
said mask is of elastomeric material, and including compressing said screen between said mask and said substrate face, and maintaining locations on said screen that lie in openings of said mask against said substrate face.

6. Apparatus for the deposition of an electrically conductive layer of precious metal on the face of a metal substrate through an opening in a mask, by the electrodeposition of the precious metal through an electrolyte onto the face of the substrate, comprising:
a screen that lies at least in said mask opening, against the face of the metal substrate, said screen having a regular pattern of through holes in which the electrolyte can lie, to produce a deposited layer having multiple recesses.

7. The apparatus described in claim 6 wherein:
said screen is formed of woven threads of electrically nonconductive material, said threads having rounded outside surfaces.

8. The apparatus described in claim 6 wherein:
said screen is formed of woven threads of electrically nonconductive material which form primarily square openings that each has a length and width or the order of 85 microns.

9. A sheet of electrically conductive material wherein:
said sheet is formed of electrolytically deposited precious metal and has an upper face that has multiple depressions in the form of a mesh, with said depressions spaced apart at a pitch on the order of 85 microns.

10. The sheet described in claim 9 wherein:
said upper face forms peaks that are substantially coplanar.

11. The sheet described in claim 9 wherein:
the maximum thickness of said sheet is between 0.2 and 2 microns.
